(19) United States
(12) Patent Application Publication
(10) Pub. No.: US 2012/0267659 A1
(43) Pub. Date: Oct. 25, 2012

(54) LED PACKAGE STRUCTURE

(75) Inventors: KAO-HSU CHOU, TAIPEI CITY (TW); CHIN-KAI HUANG, YILAN COUNTY (TW); YI-JU LI, YILAN COUNTY (TW); SHIH-MIN WU, TAOYUAN COUNTY (TW); DAWSON LIU, TAIPEI CITY (TW)

(73) Assignee: LUSTROUS TECHNOLOGY LTD., NEW TAIPEI CITY (TW)

(21) Appl. No.: 13/238,048

(22) Filed: Sep. 21, 2011

(30) Foreign Application Priority Data
Apr. 20, 2011 (TW) 100113809

(51) Int. Cl. H01L 33/50

(52) U.S. Cl. 257/98; 257/E33.061

(57) ABSTRACT

A LED package structure includes a substrate unit, a light emitting unit, a package unit, and a phosphor unit. The substrate unit includes a substrate body. The light emitting unit includes at least one light emitting element disposed on and electrically connected to the substrate body. The package unit includes a package resin body formed on the substrate body to cover the light emitting element. The package resin body has a light output surface formed on the top surface thereof to guide light beams generated by the light emitting element to leave the package resin body. The phosphor unit includes a prefabricated phosphor cap disposed on the substrate body to enclose the package resin body. The prefabricated phosphor cap is separated from the package resin body by a predetermined distance to form a receiving portion between the prefabricated phosphor cap and the package resin body.

### BACKGROUND OF THE INVENTION

1. Field of the Invention

The instant disclosure relates to a LED package structure, and more particularly, to a LED package structure using a prefabricated phosphor cap.

2. Description of Related Art

The invention of the lamp greatly changes the style of building construction and the lifestyle of human beings, allowing people to work during the night. Traditional lighting devices such as lamps that adopt incandescent bulbs, fluorescent bulbs, or power-saving bulbs have been generally well-developed and used intensively for indoor illumination.

Moreover, compared to the newly developed light-emitting-diode (LED) lamps, these traditional lamps have the disadvantages of quick attenuation, high power consumption, high heat generation, short service life, high fragility, and being not recyclable. Thus, various high-powered LED structures are created to replace the traditional light sources.

### SUMMARY OF THE INVENTION

One aspect of the instant disclosure relates to a LED package structure using a prefabricated phosphor cap.

One of the embodiments of the instant disclosure provides a LED package structure, comprising: a substrate unit, a light emitting unit, a package unit, and a phosphor unit. The substrate unit includes at least one substrate body. The light emitting unit includes at least one light emitting element disposed on the at least one substrate body and electrically connected to the at least one substrate body. The package unit includes a package resin body formed on the at least one substrate body to cover the at least one light emitting element, wherein the package resin body has a light output surface formed on the top surface thereof to guide light beams generated by the at least one light emitting element to leave the package resin body. The phosphor unit includes a prefabricated phosphor cap disposed on the at least one substrate body to enclose the package resin body, wherein the prefabricated phosphor cap is separated from the package resin body by a predetermined distance to form a receiving portion between the prefabricated phosphor cap and the package resin body.

Another one of the embodiments of the instant disclosure provides a LED package structure, comprising: a substrate unit, a light emitting unit, a frame unit, a package unit, and a phosphor unit. The substrate unit includes at least one substrate body. The light emitting unit includes at least one light emitting element disposed on the at least one substrate body and electrically connected to the at least one substrate body. The frame unit includes a surrounding reflection frame body surroundingly disposed on the at least one substrate body to form a receiving space, wherein the surrounding reflection frame body surrounds the at least one light emitting element, thus the at least one light emitting element is received in the receiving space. The package unit includes a package resin body formed on the at least one substrate body to cover the at least one light emitting element, wherein the package resin body is received in the receiving space of the surrounding reflection frame body, and the package resin body has a light output surface formed on the top surface thereof to guide light beams generated by the at least one light emitting element to leave the package resin body. The phosphor unit includes a prefabricated phosphor cap disposed on the surrounding reflection frame body to enclose the package resin body, wherein the prefabricated phosphor cap is separated from the package resin body by a predetermined distance to form a receiving portion between the prefabricated phosphor cap and the package resin body.

Furthermore, the LED package structure further comprises a light guiding unit including a light guiding resin body received in the receiving portion to guide the light beams generated by the at least one light emitting element from the package resin body to the prefabricated phosphor cap or including a liquid transparent silicone oil that fills up the receiving portion to guide the light beams generated by the at least one light emitting element from the package resin body to the prefabricated phosphor cap. In addition, the refractive index of the prefabricated phosphor cap is larger or smaller than the refractive index of the package resin body, and the refractive index of the light guiding resin body or the liquid transparent silicone oil is smaller than the refractive indexes of the package resin body and the prefabricated phosphor cap.

Therefore, because the instant disclosure can use the prefabricated phosphor cap to decrease the total reflection opportunity, the luminescence efficiency of the LED package structure Z of the instant disclosure can be increased.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, cross-sectional, schematic view of the LED package structure using a prefabricated phosphor cap according to the first embodiment of the instant disclosure;

FIG. 2 shows a lateral, cross-sectional, schematic view of the LED package structure using a prefabricated phosphor cap according to the second embodiment of the instant disclosure;

FIG. 3 shows a lateral, cross-sectional, schematic view of the LED package structure using a prefabricated phosphor cap according to the third embodiment of the instant disclosure;

FIG. 4 shows a lateral, cross-sectional, schematic view of the LED package structure using a prefabricated phosphor cap according to the fourth embodiment of the instant disclosure;

FIG. 5 shows a lateral, cross-sectional, schematic view of the LED package structure using a prefabricated phosphor cap according to the fifth embodiment of the instant disclosure;

FIG. 6 shows a lateral, cross-sectional, schematic view of the LED package structure using a prefabricated phosphor cap according to the sixth embodiment of the instant disclosure;

FIG. 7 shows a lateral, cross-sectional, schematic view of the LED package structure using a prefabricated phosphor cap according to the seventh embodiment of the instant disclosure;

FIG. 8 shows a lateral, cross-sectional, schematic view of the LED package structure using a prefabricated phosphor cap according to the eighth embodiment of the instant disclosure;

FIG. 9 shows a lateral, cross-sectional, schematic view of the LED package structure using a prefabricated phosphor cap according to the ninth embodiment of the instant disclosure;

FIG. 10 shows a lateral, cross-sectional, schematic view of the LED package structure using a prefabricated phosphor cap according to the tenth embodiment of the instant disclosure;

FIG. 11 shows a lateral, cross-sectional, schematic view of the LED package structure using a prefabricated phosphor cap according to the eleventh embodiment of the instant disclosure; and

FIG. 12 shows a lateral, cross-sectional, schematic view of the LED package structure using a prefabricated phosphor cap according to the twelfth embodiment of the instant disclosure.

### DETAILED DESCRIPTION OF THE PREFERRED EMBODIMENTS

### First Embodiment

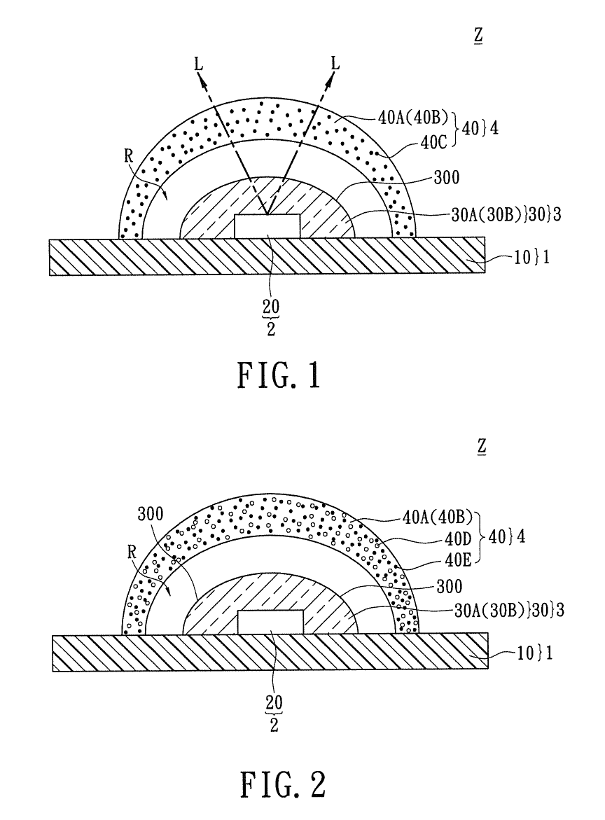

Referring to FIG. 1, where the first embodiment of the instant disclosure provides a LED package structure Z, comprising: a substrate unit 1, a light emitting unit 2, a package unit 3, and a phosphor unit 4.

The substrate unit 1 includes at least one substrate body 10. For example, the at least one substrate body 10 may be a circuit substrate, and the circuit substrate has a plurality of conductive traces (not shown) formed thereon.

The light emitting unit 2 includes at least one light emitting element 20 disposed on the at least one substrate body 10 and electrically connected to the at least one substrate body 10. Of course, the first embodiment can use a plurality of light emitting elements 20 disposed on the at least one substrate body 10 and electrically connected to the at least one substrate body 10. For example, the at least one light emitting element 20 may be a blue LED bare die, and the at least one light emitting element 20 can be electrically connected to the at least one substrate body 10 by a wire-bonding manner or a flip-chip manner.

The package unit 3 includes a package resin body 30 formed on the at least one substrate body 10 to cover the at least one light emitting element 20. The package resin body 30 has a light output surface 300 (such as spherical surface or curved surface) formed on the top surface thereof in order to guide light beams L generated by the at least one light emitting element 20 to leave the package resin body 30. In other words, the light beams L can pass through the package resin body 30 and be projected outside through the light output surface 300. In addition, the package resin body 30 may be a transparent resin body formed by silicone 30A or epoxy 30B according to different requirements. For example, liquid silicone or liquid epoxy can be formed on the at least one substrate body 10 to cover the at least one light emitting element 20 by adhesive dripping or press molding, and then liquid silicone or liquid epoxy can be baked (or cured) to form the solidified package resin body 30 made of the silicone 30A or the epoxy 30B.

The phosphor unit 4 includes a prefabricated phosphor cap 40 disposed on the at least one substrate body 10 to enclose the package resin body 30, and the prefabricated phosphor cap 40 is separated from the package resin body 30 by a predetermined distance to form a receiving portion R between the prefabricated phosphor cap 40 and the package resin body 30. For example, the receiving portion R may be an air layer between the prefabricated phosphor cap 40 and the package resin body 30. The refractive index of the prefabricated phosphor cap 40 can be larger or smaller than the refractive index of the package resin body 30, and the refractive index of the air layer is certainly smaller than the refractive indexes of the package resin body 30 and the prefabricated phosphor cap 40. In addition, the prefabricated phosphor cap 40 may be a phosphor cover formed by mixing silicone 40A and a plurality of phosphor particles 40C or by mixing epoxy 40B and a plurality of phosphor particles 40C according to different requirements.

In other words, the solidified phosphor cap 40 with the phosphor particles 40C has been manufactured to form the prefabricated phosphor cap 40 before forming the package resin body 30 on the at least one substrate body 10 to cover the at least one light emitting element 20, and then the prefabricated phosphor cap 40 can be used to enclose the package resin body 30 after forming the package resin body 30 on the at least one substrate body 10 to cover the at least one light emitting element 20.

In conclusion, because the package resin body 30 has a light output surface 300 formed on the top surface thereof, the light beams L (such as blue light source) generated by the at least one light emitting element 20 (such as blue LED bare die) can be efficiently guided from the package resin body 30 to the receiving portion R (such as the air layer). In addition, because the refractive index of the prefabricated phosphor cap 40 is larger than the refractive index of the receiving portion R (such as the air layer) to reduce the total reflection opportunity, the light beams L can be efficiently transformed from blue light source into white source through the prefabricated phosphor cap 40. In other words, when the light beams L are transmitted from one substance (such as the receiving portion R filled with the air layer) with small refractive index to another substance (such as the prefabricated phosphor cap 40) with large refractive index, most of the light beams L can efficiently pass through the prefabricated phosphor cap 40 and cannot go back to the receiving portion R by the reflection of the prefabricated phosphor cap 40. Therefore, the luminescence efficiency of the LED package structure Z of the instant disclosure can be increased by using the prefabricated phosphor cap 40.

### Second Embodiment

Referring to FIG. 2, where the second embodiment of the instant disclosure provides a LED package structure Z, comprising: a substrate unit 1, a light emitting unit 2, a package unit 3, and a phosphor unit 4. Comparing FIG. 2 with FIG. 1, the difference between the second embodiment and the first embodiment is that: in the second embodiment, the prefabricated phosphor cap 40 may be a phosphor cover formed by mixing silicone 40A, a plurality of first phosphor particles 40D, and a plurality of second phosphor particles 40E or by mixing epoxy 40B, a plurality of first phosphor particles 40D, and a plurality of second phosphor particles 40E. Of course, the instant disclosure can use more than two types of phosphor particles to mix with the silicone 40A or the epoxy 40B according to different requirements.

### Third Embodiment

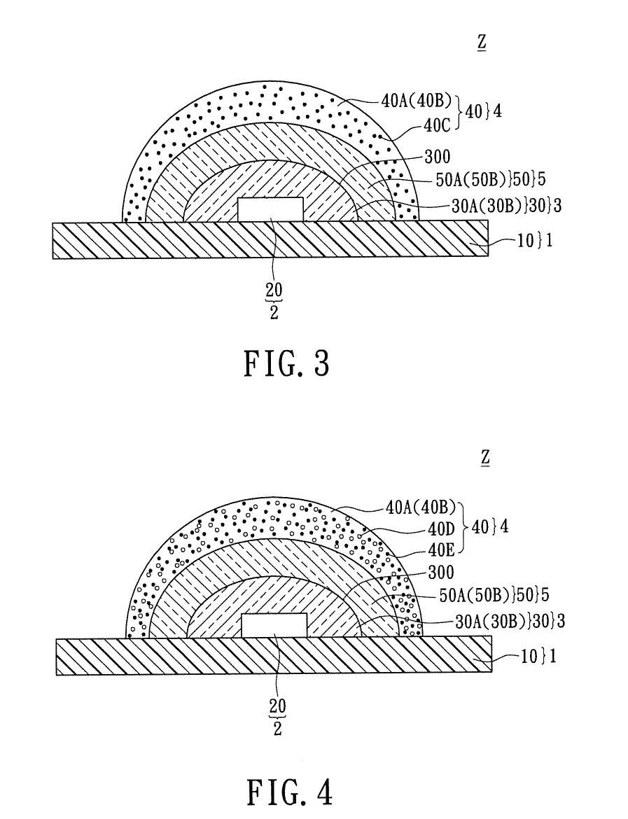

Referring to FIG. 3, where the third embodiment of the instant disclosure provides a LED package structure Z, comprising: a substrate unit 1, a light emitting unit 2, a package unit 3, and a phosphor unit 4. Comparing FIG. 3 with FIG. 1, the difference between the third embodiment and the first embodiment is that: the LED package structure Z of the third embodiment further comprises a light guiding unit 5 including a light guiding resin body 50 received in the receiving portion R (as shown in FIG. 1) in order to guide the light beams L generated by the at least one light emitting element 20 from the package resin body 30 to the prefabricated phosphor cap 40. Moreover, the light guiding resin body 50 has a bottom surface tightly contacting the top surface of the package resin body 30 and a top surface tightly contacting the bottom surface of the prefabricated phosphor cap 40. For example, the light guiding resin body 50 may be a transparent resin body formed by silicon 50A or epoxy 50B. The refractive index of the prefabricated phosphor cap 40 is larger or smaller than the refractive index of the package resin body 30, and the refractive index of the light guiding resin body 50 is certainly smaller than the refractive indexes of the package resin body 30 and the prefabricated phosphor cap 40.

Therefore, because the refractive index of the prefabricated phosphor cap 40 is larger or smaller than the refractive index of the package resin body 30, and the refractive index of the light guiding resin body 50 is certainly smaller than the refractive indexes of the package resin body 30 and the prefabricated phosphor cap 40 to reduce the total reflection opportunity, the light beams L sequentially passing through the package resin body 30, and the light guiding resin body 50 can be efficiently transformed from blue light source into white source through the prefabricated phosphor cap 40. In other words, when the light beams L are transmitted from one substance (such as the light guiding resin body 50) with small refractive index to another substance (such as the prefabricated phosphor cap 40) with large refractive index, most of the light beams L can efficiently pass through the prefabricated phosphor cap 40 and cannot go back to the light guiding resin body 50 by the reflection of the prefabricated phosphor cap 40. Therefore, the luminescence efficiency of the LED package structure Z of the instant disclosure can be increased by using the prefabricated phosphor cap 40.

Of course, the light guiding resin body 50 can be replaced by liquid transparent silicone oil, thus the receiving portion R is filled with the liquid transparent silicone oil. In other words, the light guiding unit 5 includes a liquid transparent silicone oil that fills up the receiving portion R to guide the light beams L generated by the at least one light emitting element 20 from the package resin body 30 to the prefabricated phosphor cap 40. In addition, the refractive index of the prefabricated phosphor cap 40 is larger or smaller than the refractive index of the package resin body 30, and the refractive index of the liquid transparent silicone oil is certainly smaller than the refractive indexes of the package resin body 30 and the prefabricated phosphor cap 40.

### Fourth Embodiment

Referring to FIG. 4, where the fourth embodiment of the instant disclosure provides a LED package structure Z, comprising: a substrate unit 1, a light emitting unit 2, a package unit 3, and a phosphor unit 4. Comparing FIG. 4 with FIG. 3, the difference between the fourth embodiment and the third embodiment is that: in the fourth embodiment, the prefabricated phosphor cap 40 may be a phosphor cover formed by mixing silicone 40A, a plurality of first phosphor particles 40D, and a plurality of second phosphor particles 40E or by mixing epoxy 40B, a plurality of first phosphor particles 40D, and a plurality of second phosphor particles 40E. Of course, the instant disclosure can use more than two types of phosphor particles to mix with the silicone 40A or the epoxy 40B according to different requirements.

### Fifth Embodiment

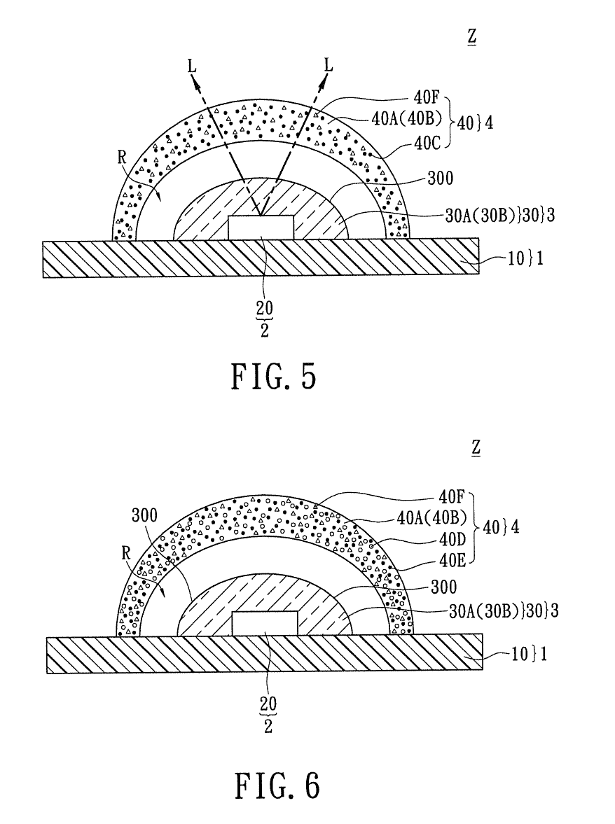

Referring to FIG. 5, where the fifth embodiment of the instant disclosure provides a LED package structure Z, comprising: a substrate unit 1, a light emitting unit 2, a package unit 3, and a phosphor unit 4. Comparing FIG. 5 with FIG. 1, the difference between the fifth embodiment and the first embodiment is that: in the fifth embodiment, the prefabricated phosphor cap 40 may be a phosphor cover formed by mixing silicone 40A, a plurality of phosphor particles 40C, and a plurality of light diffusing particles 40F or by mixing epoxy 40B, a plurality of phosphor particles 40C, and a plurality of light diffusing particles 40F. Therefore, the light uniforming effect of the LED package structure Z of the instant disclosure can be increased by using the light diffusing particles 40F to uniform the light beams L generated by the at least one light emitting element 20.

### Sixth Embodiment

Referring to FIG. 6, where the sixth embodiment of the instant disclosure provides a LED package structure Z, comprising: a substrate unit 1, a light emitting unit 2, a package unit 3, a phosphor unit 4, and frame unit 6. Comparing FIG. 6 with FIG. 2, the difference between the sixth embodiment and the second embodiment is that: in the sixth embodiment, the prefabricated phosphor cap 40 may be a phosphor cover formed by mixing silicone 40A, a plurality of first phosphor particles 40D, a plurality of second phosphor particles 40E, and a plurality of light diffusing particles 40F or by mixing epoxy 40B, a plurality of first phosphor particles 40D, a plurality of second phosphor particles 40E, and a plurality of light diffusing particles 40F. Therefore, the light uniforming effect of the LED package structure Z of the instant disclosure can be increased by using the light diffusing particles 40F to uniform the light beams L generated by the at least one light emitting element 20.

### Seventh Embodiment

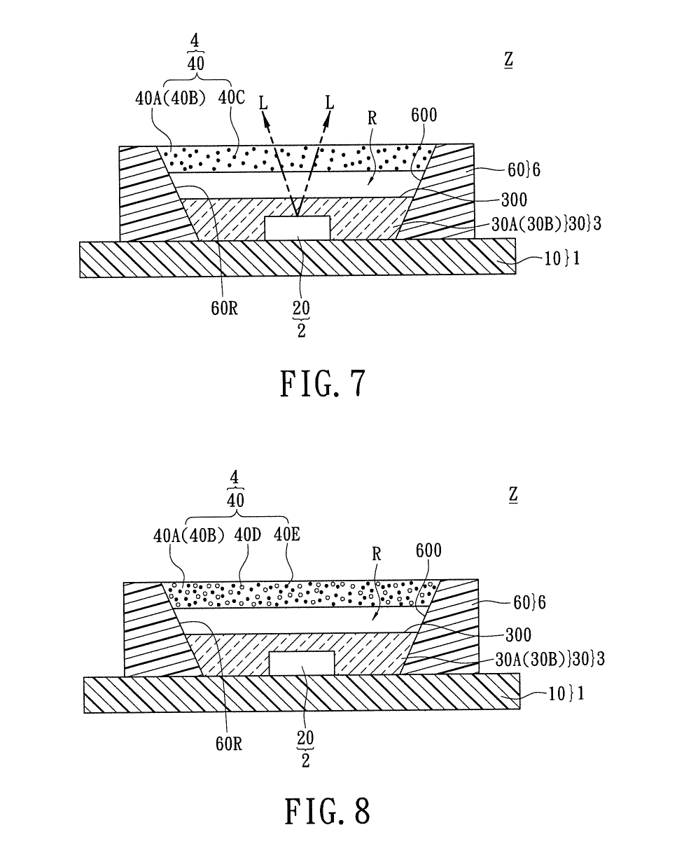

Referring to FIG. 7, where the seventh embodiment of the instant disclosure provides a LED package structure Z, comprising: a substrate unit 1, a light emitting unit 2, a package unit 3, a phosphor unit 4, and frame unit 6. The substrate unit 1 includes at least one substrate body 10. The light emitting unit 2 includes at least one light emitting element 20 disposed on the at least one substrate body 10 and electrically connected to the at least one substrate body 10. The frame unit 6 includes a surrounding reflection frame body 60 surroundingly disposed on the at least one substrate body 10 to form a receiving space 60R. The surrounding reflection frame body 60 surrounds the at least one light emitting element 20, thus the at least one light emitting element 20 can be received in the receiving space 60R. The package unit 3 includes a package resin body 30 formed on the at least one substrate body 10 to cover the at least one light emitting element 20. The package resin body 30 is received in the receiving space 60R of the surrounding reflection frame body 60, and the package resin body 30 has a light output surface 300 formed on the top surface thereof to guide light beams L generated by the at least one light emitting element 20 to leave the package resin body 30. The phosphor unit 4 includes a prefabricated phosphor cap 40 disposed on the surrounding reflection frame body 60 to enclose the package resin body 30, and the prefabricated phosphor cap 40 is separated from the package resin body 30 by a predetermined distance to form a receiving portion R between the prefabricated phosphor cap 40 and the package resin body 30.

Comparing to FIG. 7 with FIG. 1, the difference between the seventh embodiment and the first embodiment is that: the seventh embodiment further comprises a frame unit 6, and the prefabricated phosphor cap 40 is surrounded and supported by the surrounding reflection frame body 60. Moreover, the surrounding reflection frame body 60 has an inner reflection inclined surface 600 in the receiving space 60R to tightly contact the package resin body 30 and the prefabricated phosphor cap 40, and the inner reflection inclined surface 600 is gradually outwardly expanded from bottom to top.

### Eighth Embodiment

Referring to FIG. 8, where the eighth embodiment of the instant disclosure provides a LED package structure Z, comprising: a substrate unit 1, a light emitting unit 2, a package unit 3, a phosphor unit 4, and frame unit 6. Comparing FIG. 8 with FIG. 7, the difference between the eighth embodiment and the seventh embodiment is that: in the eighth embodiment, the prefabricated phosphor cap 40 may be a phosphor cover formed by mixing silicone 40A, a plurality of first phosphor particles 40D, and a plurality of second phosphor particles 40E or by mixing epoxy 40B, a plurality of first phosphor particles 40D, and a plurality of second phosphor particles 40E. Of course, the instant disclosure can use more than two types of phosphor particles to mix with the silicone 40A or the epoxy 40B according to different requirements.

### Ninth Embodiment

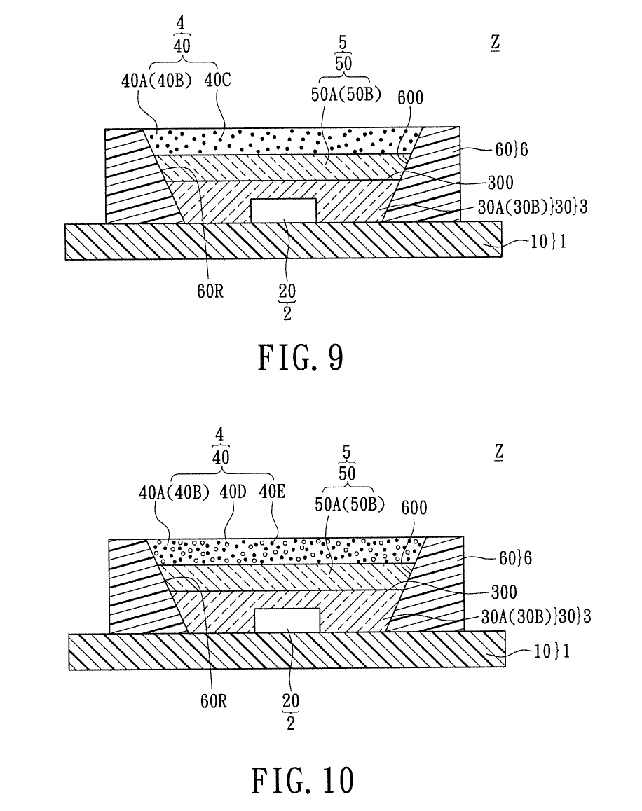

Referring to FIG. 9, where the ninth embodiment of the instant disclosure provides a LED package structure Z, comprising: a substrate unit 1, a light emitting unit 2, a package unit 3, a phosphor unit 4, and frame unit 6. Comparing FIG. 9 with FIG. 7, the difference between the ninth embodiment and the seventh embodiment is that: the LED package structure Z of the ninth embodiment further comprises a light guiding unit 5 including a light guiding resin body 50 received in the receiving portion R (as shown in FIG. 1) in order to guide the light beams L generated by the at least one light emitting element 20 from the package resin body 30 to the prefabricated phosphor cap 40. Moreover, the light guiding resin body 50 has a bottom surface tightly contacting the top surface of the package resin body 30 and a top surface tightly contacting the bottom surface of the prefabricated phosphor cap 40. In addition, the surrounding reflection frame body 60 has an inner reflection inclined surface 600 in the receiving space R to tightly contact the package resin body 30, the light guiding resin body 50, and the prefabricated phosphor cap 40. For example, the light guiding resin body 50 may be a transparent resin body formed by silicon 50A or epoxy 50B. The refractive index of the prefabricated phosphor cap 40 is larger or smaller than the refractive index of the package resin body 30, and the refractive index of the light guiding resin body 50 is certainly smaller than the refractive indexes of the package resin body 30 and the prefabricated phosphor cap 40.

Therefore, because the refractive index of the prefabricated phosphor cap 40 is larger or smaller than the refractive index of the package resin body 30, and the refractive index of the light guiding resin body 50 is certainly smaller than the refractive indexes of the package resin body 30 and the prefabricated phosphor cap 40 to reduce the total reflection opportunity, the light beams L sequentially passing through the package resin body 30 and the light guiding resin body 50 can be efficiently transformed from blue light source into white source through the prefabricated phosphor cap 40. In other words, when the light beams L are transmitted from one substance (such as the light guiding resin body 50) with small refractive index to another substance (such as the prefabricated phosphor cap 40) with large refractive index, most of the light beams L can efficiently pass through the prefabricated phosphor cap 40 and cannot go back to the light guiding resin body 50 by the reflection of the prefabricated phosphor cap 40. Therefore, the luminescence efficiency of the LED package structure Z of the instant disclosure can be increased by using the prefabricated phosphor cap 40.

Of course, the light guiding resin body 50 can be replaced by liquid transparent silicone oil, thus the receiving portion R is filled with the liquid transparent silicone oil. In other words, the light guiding unit 5 includes a liquid transparent silicone oil that fills up the receiving portion R to guide the light beams L generated by the at least one light emitting element 20 from the package resin body 30 to the prefabricated phosphor cap 40. In addition, the refractive index of the prefabricated phosphor cap 40 is larger or smaller than the refractive index of the package resin body 30, and the refractive index of the liquid transparent silicone oil is certainly smaller than the refractive indexes of the package resin body 30 and the prefabricated phosphor cap 40.

### Tenth Embodiment

Referring to FIG. 10, where the tenth embodiment of the instant disclosure provides a LED package structure Z, comprising: a substrate unit 1, a light emitting unit 2, a package unit 3, a phosphor unit 4, and frame unit 6. Comparing FIG. 10 with FIG. 9, the difference between the tenth embodiment and the ninth embodiment is that: in the tenth embodiment, the prefabricated phosphor cap 40 may be a phosphor cover formed by mixing silicone 40A, a plurality of first phosphor particles 40D, and a plurality of second phosphor particles 40E or by mixing epoxy 40B, a plurality of first phosphor particles 40D, and a plurality of second phosphor particles 40E. Of course, the instant disclosure can use more than two types of phosphor particles to mix with the silicone 40A or the epoxy 40B according to different requirements.

### Eleventh Embodiment

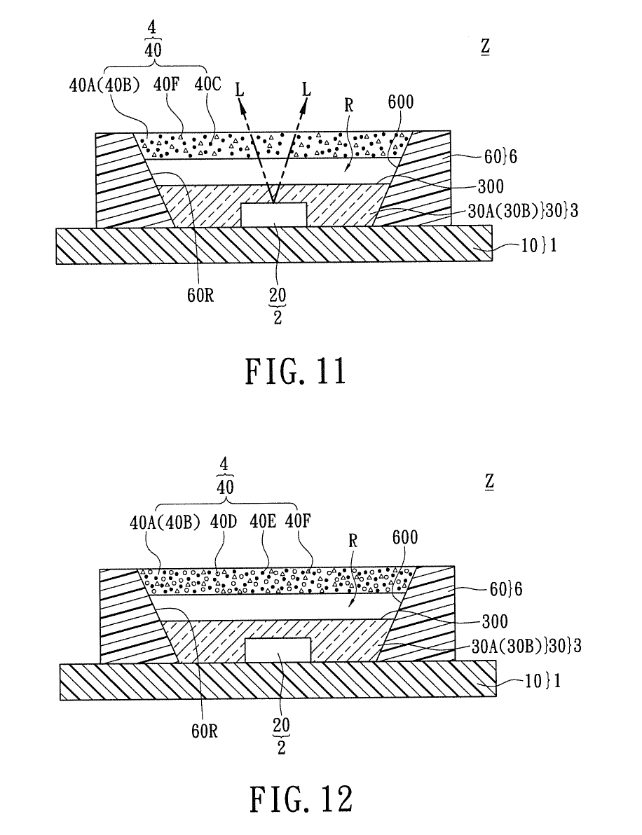

Referring to FIG. 11, where the eleventh embodiment of the instant disclosure provides a LED package structure Z, comprising: a substrate unit 1, a light emitting unit 2, a package unit 3, a phosphor unit 4, and frame unit 6. Comparing FIG. 11 with FIG. 7, the difference between the eleventh embodiment and the seventh embodiment is that: in the eleventh embodiment, the prefabricated phosphor cap 40 may be a phosphor cover formed by mixing silicone 40A, a plurality of phosphor particles 40C, and a plurality of light diffusing particles 40F or by mixing epoxy 40B, a plurality of phosphor particles 40C, and a plurality of light diffusing particles 40F. Therefore, the light uniforming effect of the LED package structure Z of the instant disclosure can be increased by using the light diffusing particles 40F to uniform the light beams L generated by the at least one light emitting element 20.

### Twelfth Embodiment

Referring to FIG. 12, where the twelfth embodiment of the instant disclosure provides a LED package structure Z, comprising: a substrate unit 1, a light emitting unit 2, a package unit 3, a phosphor unit 4, and frame unit 6. Comparing FIG. 12 with FIG. 8, the difference between the twelfth embodiment and the eighth embodiment is that: in the twelfth embodiment, the prefabricated phosphor cap 40 may be a phosphor cover formed by mixing silicone 40A, a plurality of first phosphor particles 40D, a plurality of second phosphor particles 40E, and a plurality of light diffusing particles 40F or by mixing epoxy 40B, a plurality of first phosphor particles 40D, a plurality of second phosphor particles 40E, and a plurality of light diffusing particles 40F. Therefore, the light uniforming effect of the LED package structure Z of the instant disclosure can be increased by using the light diffusing particles 40F to uniform the light beams L generated by the at least one light emitting element 20.

In conclusion, because the instant disclosure can use the prefabricated phosphor cap to decrease the total reflection opportunity, the luminescence efficiency of the LED package structure Z of the instant disclosure can be increased.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A LED package structure, comprising:
a substrate unit including at least one substrate body;
a light emitting unit including at least one light emitting element disposed on the at least one substrate body and electrically connected to the at least one substrate body;
a package unit including a package resin body formed on the at least one substrate body to cover the at least one light emitting element, wherein the package resin body has a light output surface formed on the top surface thereof to guide light beams generated by the at least one light emitting element to leave the package resin body; and
a phosphor unit including a prefabricated phosphor cap disposed on the at least one substrate body to enclose the package resin body, wherein the prefabricated phosphor cap is separated from the package resin body by a predetermined distance to form a receiving portion between the prefabricated phosphor cap and the package resin body.

2. The LED package structure of claim 1, wherein the package resin body is a transparent resin body formed by silicone or epoxy, the receiving portion is an air layer between the prefabricated phosphor cap and the package resin body, the refractive index of the prefabricated phosphor cap is larger or smaller than the refractive index of the package resin body, and the refractive index of the air layer is smaller than the refractive indexes of the package resin body and the prefabricated phosphor cap.

3. The LED package structure of claim 1, wherein the prefabricated phosphor cap is a phosphor cover formed by mixing silicone and a plurality of phosphor particles or by mixing epoxy and a plurality of phosphor particles.

4. The LED package structure of claim 1, wherein the prefabricated phosphor cap is a phosphor cover formed by mixing silicone, a plurality of phosphor particles, and a plurality of light diffusing particles or by mixing epoxy, a plurality of phosphor particles, and a plurality of light diffusing particles.

5. The LED package structure of claim 1, wherein the prefabricated phosphor cap is a phosphor cover formed by mixing silicone, a plurality of first phosphor particles, and a plurality of second phosphor particles or by mixing epoxy, a plurality of first phosphor particles, and a plurality of second phosphor particles.

6. The LED package structure of claim 1, wherein the prefabricated phosphor cap is a phosphor cover formed by mixing silicone, a plurality of first phosphor particles, a plurality of second phosphor particles, and a plurality of light diffusing particles or by mixing epoxy, a plurality of first phosphor particles, a plurality of second phosphor particles, and a plurality of light diffusing particles.

7. The LED package structure of claim 1, further comprising a light guiding unit including a light guiding resin body received in the receiving portion to guide the light beams generated by the at least one light emitting element from the package resin body to the prefabricated phosphor cap, wherein the light guiding resin body has a bottom surface tightly contacting the top surface of the package resin body and a top surface tightly contacting the bottom surface of the prefabricated phosphor cap, the light guiding resin body is a transparent resin body formed by silicon or epoxy, the prefabricated phosphor cap is a phosphor cover formed by mixing silicone and a plurality of phosphor particles or by mixing epoxy and a plurality of phosphor particles, the refractive index of the prefabricated phosphor cap is larger or smaller than the refractive index of the package resin body, and the refractive index of the light guiding resin body is smaller than the refractive indexes of the package resin body and the prefabricated phosphor cap.

8. The LED package structure of claim 1, further comprising a light guiding unit including a liquid transparent silicone oil that fills up the receiving portion to guide the light beams generated by the at least one light emitting element from the package resin body to the prefabricated phosphor cap, wherein the refractive index of the prefabricated phosphor cap is larger or smaller than the refractive index of the package resin body, and the refractive index of the liquid transparent silicone oil is smaller than the refractive indexes of the package resin body and the prefabricated phosphor cap.

9. A LED package structure, comprising:
a substrate unit including at least one substrate body;
a light emitting unit including at least one light emitting element disposed on the at least one substrate body and electrically connected to the at least one substrate body;
a frame unit including a surrounding reflection frame body surroundingly disposed on the at least one substrate body to form a receiving space, wherein the surrounding reflection frame body surrounds the at least one light emitting element, thus the at least one light emitting element is received in the receiving space;
a package unit including a package resin body formed on the at least one substrate body to cover the at least one light emitting element, wherein the package resin body is received in the receiving space of the surrounding reflection frame body, and the package resin body has a light output surface formed on the top surface thereof to guide light beams generated by the at least one light emitting element to leave the package resin body; and
a phosphor unit including a prefabricated phosphor cap disposed on the surrounding reflection frame body to enclose the package resin body, wherein the prefabricated phosphor cap is separated from the package resin body by a predetermined distance to form a receiving portion between the prefabricated phosphor cap and the package resin body.

10. The LED package structure of claim 9, wherein the package resin body is a transparent resin body formed by silicone or epoxy, the receiving portion is an air layer between the prefabricated phosphor cap and the package resin body, the refractive index of the prefabricated phosphor cap is larger or smaller than the refractive index of the package resin body, and the refractive index of the air layer is smaller than the refractive indexes of the package resin body and the prefabricated phosphor cap.

11. The LED package structure of claim 9, wherein the prefabricated phosphor cap is a phosphor cover formed by mixing silicone and a plurality of phosphor particles or by mixing epoxy and a plurality of phosphor particles.

12. The LED package structure of claim 9, wherein the prefabricated phosphor cap is a phosphor cover formed by mixing silicone, a plurality of phosphor particles, and a plurality of light diffusing particles or by mixing epoxy, a plurality of phosphor particles, and a plurality of light diffusing particles.

13. The LED package structure of claim 9, wherein the prefabricated phosphor cap is a phosphor cover formed by mixing silicone, a plurality of first phosphor particles, and a plurality of second phosphor particles or by mixing epoxy, a plurality of first phosphor particles, and a plurality of second phosphor particles.

14. The LED package structure of claim 9, wherein the prefabricated phosphor cap is a phosphor cover formed by mixing silicone, a plurality of first phosphor particles, a plurality of second phosphor particles, and a plurality of light diffusing particles or by mixing epoxy, a plurality of first phosphor particles, a plurality of second phosphor particles, and a plurality of light diffusing particles.

15. The LED package structure of claim 9, wherein the prefabricated phosphor cap is surrounded and supported by the surrounding reflection frame body.

16. The LED package structure of claim 9, wherein the surrounding reflection frame body has an inner reflection inclined surface in the receiving space to tightly contact the package resin body and the prefabricated phosphor cap, and the inner reflection inclined surface is gradually outwardly expanded from bottom to top.

17. The LED package structure of claim 9, further comprising a light guiding unit including a light guiding resin body received in the receiving portion to guide the light beams generated by the at least one light emitting element from the package resin body to the prefabricated phosphor cap, wherein the light guiding resin body has a bottom surface tightly contacting the top surface of the package resin body and a top surface tightly contacting the bottom surface of the prefabricated phosphor cap, the light guiding resin body is a transparent resin body formed by silicon or epoxy, the prefabricated phosphor cap is a phosphor cover formed by mixing silicone and a plurality of phosphor particles or by mixing epoxy and a plurality of phosphor particles, the refractive index of the prefabricated phosphor cap is larger or smaller than the refractive index of the package resin body, and the refractive index of the light guiding resin body is smaller than the refractive indexes of the package resin body and the prefabricated phosphor cap.

18. The LED package structure of claim 17, wherein the surrounding reflection frame body has an inner reflection inclined surface in the receiving space to tightly contact the package resin body, the light guiding resin body, and the prefabricated phosphor cap, and the inner reflection inclined surface is gradually outwardly expanded from bottom to top.

19. The LED package structure of claim 9, further comprising a light guiding unit including a liquid transparent silicone oil received in the receiving portion to guide the light beams generated by the at least one light emitting element from the package resin body to the prefabricated phosphor cap, wherein the refractive index of the prefabricated phosphor cap is larger or smaller than the refractive index of the package resin body, and the refractive index of the liquid transparent silicone oil is smaller than the refractive indexes of the package resin body and the prefabricated phosphor cap.
